(19) United States
(12) Patent Application Publication
(10) Pub. No.: US 2010/0073068 A1
(43) Pub. Date: Mar. 25, 2010

(54) FUNCTIONAL BLOCK LEVEL THERMAL CONTROL

(76) Inventors: Hanwoo Cho, Acton, MA (US); Alexander Branover, Chestnut Hill, MA (US); Jonathan D. Hauke, Lexington, MA (US)

Correspondence Address: MHKKG / GLOBALFOUNDRIES, P.O. Box 398, Austin, TX, 78767-0698, US

(21) Appl. No.: 12/235,155

(22) Filed: Sep. 22, 2008

(51) Int. Cl. H03K 3/011

(52) U.S. Cl. 327/513

(57) ABSTRACT

An integrated circuit. The integrated circuit includes a plurality of functional units, wherein each of the plurality of functional units is implemented on a die of the integrated circuit. Each of the functional units includes one or more temperature sensors. The integrated circuit further includes a temperature control unit coupled to each of the functional units, wherein the temperature control unit is configured to monitor a temperature of each of the plurality of functional units based on temperature information provided from the temperature sensors. The temperature control unit is configured to, if the temperature exceeds a first threshold value for a particular one of the plurality of functional units, perform a first temperature control action on the particular one of the plurality of functional units independently of other ones of the plurality of functional units.

### BACKGROUND OF THE INVENTION

1. Field of the Invention

This invention relates to electronic circuits, and more particularly, to the thermal monitoring and control of electronic circuits.

2. Description of the Related Art

Many integrated circuits (IC's), both analog and digital, employ temperature monitoring and control. Typical IC's include one or more temperature sensors to monitor the temperature at various locations therein. The temperature sensors are typically coupled to a control unit, which receives the temperature information. The control unit may use the temperature information to perform various actions that can affect the operation of the IC.

In one example, a control unit may compare one or more received temperatures with a preset temperature threshold. If one of the received temperatures exceeds the threshold, the control unit may respond by reducing the speed of a clock used internally by the IC. Alternatively, a voltage present on a power plane of the IC may be lowered, and in some cases, both the voltage and the clock speed may be lowered. If the received temperature exceeds the threshold by a large enough amount, or does not fall responsive to reducing the voltage and/or clock speed, the IC may be shut down. If the IC is not shut down by a temperature control action, the voltage level and/or clock speed may be raised again once the temperature has fallen by at least a predetermined amount.

Temperature sensors are typically placed throughout the IC, often times in locations that are known to generate more heat than other areas. These temperature sensors may each be coupled to the control unit. The control unit can perform temperature control actions based on temperature readings from one or more of the sensors.

### SUMMARY OF THE INVENTION

An integrated circuit is disclosed. In one embodiment, the integrated circuit includes a plurality of functional units, wherein each of the plurality of functional units is implemented on a die of the integrated circuit. Each of the functional units includes one or more temperature sensors. The integrated circuit further includes a temperature control unit coupled to each of the functional units, wherein the temperature control unit is configured to monitor a temperature of each of the plurality of functional units based on temperature information provided from the temperature sensors. The temperature control unit is configured to, if the temperature exceeds a first threshold value for a particular one of the plurality of functional units, perform a first temperature control action on the particular one of the plurality of functional units independently of other ones of the plurality of functional units.

A method for functional block level thermal control is also disclosed. In one embodiment, the method comprises receiving temperature readings from each of a plurality of functional units implemented on an integrated circuit die and determining if a temperature reading from any of the plurality of functional units exceeds a first threshold. If the temperature exceeds a first threshold value for a particular one of the plurality of functional units, performing a first temperature control action on the particular one of the plurality of functional units independently of other ones of the plurality of functional units.

In one embodiment, the integrated circuit is a processor, such as a microprocessor suitable for use in a computer system. The processor may include two or more processor cores and a memory controller hub (i.e. a northbridge). A graphics processing unit may also be included. In other embodiments, the integrated circuit may be a digital signal processor, an ASIC (application specific IC), or other type of integrated circuit wherein temperature control as disclosed herein is appropriate.

Various temperature control actions may include reducing a clock frequency or reducing a voltage to the particular functional block upon which the action is taken. In embodiments wherein the integrated circuit is a multi-core processor, a temperature control action may include shifting a processor workload from one core to another. A temperature control action may also include shutting down the integrated circuit if a global temperature maximum is exceeded, or if the temperature control action fails to reduce the temperature of the functional unit upon which it was taken.

### BRIEF DESCRIPTION OF THE DRAWINGS

Other aspects of the invention will become apparent upon reading the following detailed description and upon reference to the accompanying drawings in which:

FIG. 1 is a block diagram of one embodiment of an integrated circuit having a plurality of functional units;

FIG. 2 is a block diagram of one embodiment of a functional unit having a plurality of temperature sensors;

FIG. 3 is a block diagram of one embodiment of a temperature control unit;

FIG. 4 is a block diagram of one embodiment of a multi-core processor having an integrated memory controller hub and graphics processing unit; and

FIG. 5 is a flow diagram of one embodiment of a method for providing functional block level thermal control for an integrated circuit.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

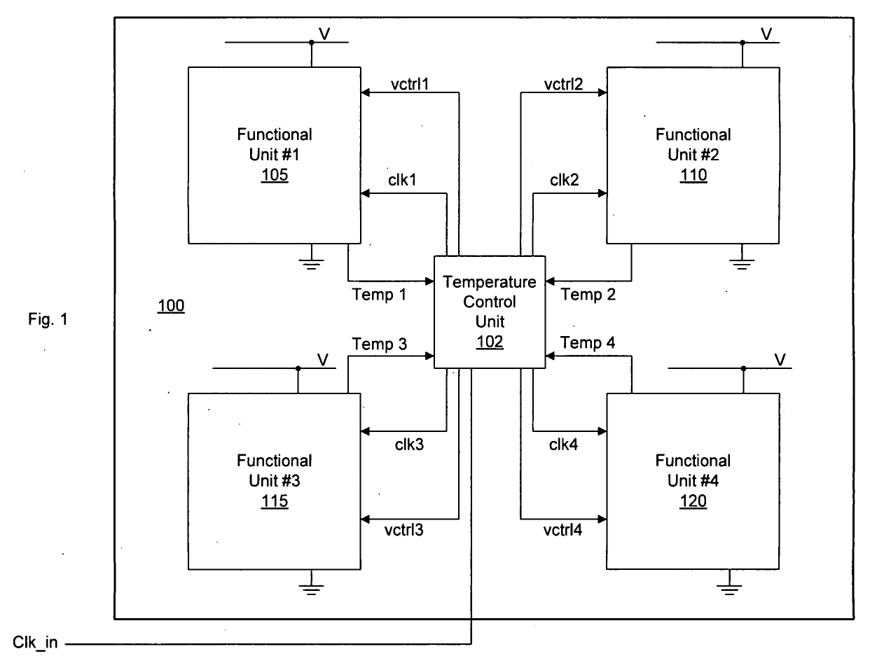

FIG. 1 is a block diagram of one embodiment of an integrated circuit (IC) having a plurality of functional units. In he embodiment shown, IC 100 includes four functional units 105, 110, 115, and 120. These functional units may be identical in some embodiments, or may be different in others. Each of the functional units 105-120 perform various functions during the operation of IC 100.

IC 100 also includes a temperature control unit (TCU) 102. TCU 102 is coupled to receive temperature indications temp1-temp4 from functional units 105-120, respectively. These temperature indications may be constantly monitored by TCU 102, or may be reported on a periodic basis. TCU 102 is further configured to perform temperature control actions on each of the functional units 105-120 independently of one another. For example, if functional unit 105 is reporting a temperature that is below a certain threshold, while functional unit 110 is reporting a temperature that is above the threshold, TCU 102 can perform a temperature control action on functional unit 110 while functional unit 105 remains unaffected. Thus, TCU 102 is configured to provide thermal control at a functional block level, rather than at a chip level.

In some embodiments, the temperature thresholds at which TCU 102 may initiate a temperature control action may be the same for each of functional units 105-120. In other embodiments, the temperature thresholds at which TCU 102 may initiate a temperature control action may be different for one or more of the functional units with respect to other ones of the functional units. This includes embodiments wherein the temperature thresholds are unique for each of functional units 105-120.

In the embodiment shown, each of the functional units 105-120 each includes a voltage plane through which power is supplied independent of power supplied to the other functional units. Thus, the voltages on the voltage planes for each of the functional units can be set independently of one another, even if all of the functional units initially receive power from the same source. TCU 102 is coupled to provide a voltage control signal (e.g., vctrl1 to functional unit 105) to each of the functional units. A voltage control signal received by a corresponding functional unit can be used to increase or decrease the voltage present on its respective voltage plane. For example, if functional unit 105 is reporting a temperature that is exceeding a temperature threshold, TCU 102 may, through the voltage control signal vctrl1, reduce the voltage at which functional unit 105 is operating. This may be performed independent of the voltage at which the other functional units 110-120 are operating. The reducing of the voltage may result in a corresponding reduction of power consumption, and thereby an eventual decrease in temperature.

TCU 102 is further coupled to receive a clock signal, clk_in, which is the primary clock signal received by IC 100. Functional units 105-120 are configured to receive clock signals clk1, clk2, clk3, and clk4, respectively. Each of clock signals clk1-clk4 is generated based on the primary clock signal. TCU 102 is further configured to control the frequency of clock signals clk1-clk4 based on temperature data that is reported by functional units 105-120. For example, if functional unit 105 reports a temperature that exceeds a predetermined temperature threshold, TCU 102 may lower the frequency of clock signal clk1. The control of the clock signal frequencies may be performed independently for each of the functional units. Thus, a change in the clock frequency for a clock signal provided to one functional unit need not affect the frequencies of the respective clock signals provided to other ones of the functional units.

In general, TCU 102 is configured to perform temperature control actions for each of the functional units independent of actions performed on other ones of the units, in order to provide thermal control at the functional block level. In the embodiment shown, a temperature control action performed for a given functional unit may result in the changing of a frequency of a clock signal to the functional unit, changing of the voltage provided to a voltage plane of the functional unit, or both. A temperature control action may also result in a removal of power and a complete shutdown of a functional unit in some cases.

TCU 102 may perform temperature control actions based on a number of different thresholds. For example, if a reported temperature from a functional unit exceeds a maximum allowable temperature, TCU 102 may perform a temperature control action such as reducing its respective clock frequency or voltage in an attempt to reduce the temperature of the functional unit. If a reported temperature falls below a minimum threshold, TCU 102 may increase the clock frequency, the voltage, or both for the reporting functional unit in order to allow for increased performance. TCU 102 may also perform temperature control actions based on one or more intermediate temperature thresholds that are between maximum and minimum values.

Multiple temperature control actions may be performed in cases where a given functional unit is slow to respond to a first temperature control action. For example, a temperature exceeding a maximum threshold is reported to TCU 102 by one of the functional units, the frequency of that clock signal and/or the voltage may be reduced. If a subsequent temperature reported by the same functional unit continues to exceed the threshold, a second temperature control action may be performed. This second temperature control action may also include a reduction in clock frequency and/or a reduction in power, or a complete shutdown of the functional unit.

In some embodiments, TCU 102 may also monitor not only the reported temperatures, but may also calculate temperature gradients and take action based on these gradients. For example, if a temperature reported by a functional unit causes TCU 102 to perform a temperature control action intended to reduce the temperature of that functional unit, a subsequent action be performed if it is determined that the temperature has not fallen by a certain amount, even if the temperature has fallen below a threshold value. Similarly, if a calculated temperature gradient indicates that temperature is rising at a rapid rate in a given functional unit, TCU 102 may perform a temperature control action even if the most recent reported temperature for that functional unit has not exceeded an intermediate or maximum threshold value. In effect, TCU 102 may perform temperature control actions based on reported temperatures, predetermined temperature thresholds, calculated temperature gradients, and temperature gradient thresholds.

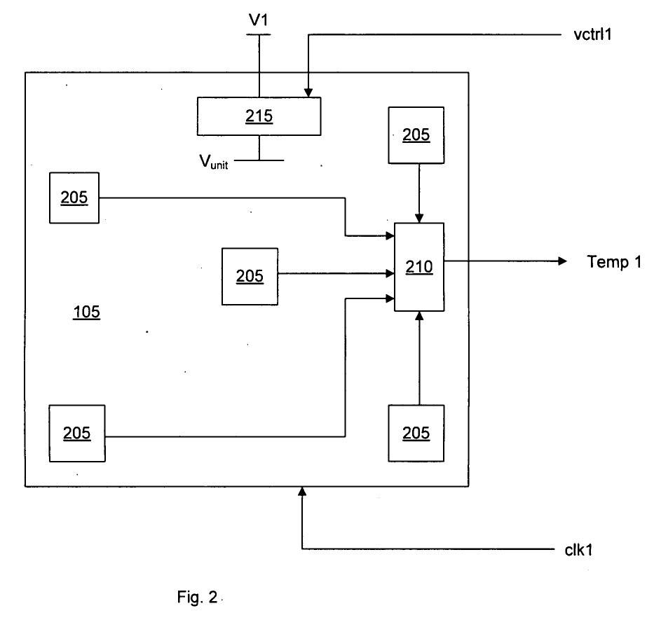

Turning now to FIG. 2, a block diagram of one embodiment of a functional unit having a plurality of temperature sensors. In this particular drawing, functional unit 105 is used for the purposes of illustration, although the same concepts may be applied to any one of the functional units. It is also noted, for the sake of clarity, the actual functional logic of the functional unit is not shown, although its presence is understood nonetheless.

In the embodiment shown, functional unit 105 includes five temperature sensors IS 205. Other embodiments may include a greater or lesser number of temperature sensors, with embodiments having a few as one temperature sensor being possible. Temperature sensors 205 are distributed at various points within functional unit 105, as different portions of the functional unit may have different thermal properties. The exact distribution of temperature sensors may thus vary from one functional unit to the next. In one embodiment, temperature sensors 205 may be implemented using ring oscillators, although different embodiments may use any suitable implementation.

Each of temperature sensors 205 is coupled to temperature filter 210. Indications of temperature from each of temperature sensors 205 are received by temperature filter 210, which is configured to determine which of the temperature sensors is reporting the highest temperature within the functional unit. The high temperature for the functional unit is then conveyed from temperature filter 210 to TCU 102 (via the line labeled ‘tempt’ in this particular example). Thus, temperature filter 210 effectively ‘filters’ out the lower temperature readings and reports only the highest temperature reading for its respective functional block. In some embodiments, temperature filter 210 may be configured to select both the highest reported temperature as well as the lowest reported temperature in functional unit 105.

Functional unit 105 also includes a voltage control unit 215. Voltage supply V is coupled to supply power to voltage control unit 215, which is in turn configured to provide power to the voltage plane of the functional unit, Vᵤₙᵢₜ. The voltage applied to voltage plane Vᵤₙᵢₜ may be increased or decreased based on the control signal vctrl1 received from TCU 102. For example, vtctrl1 may direct voltage control unit 215 to reduce the voltage on voltage plane Vᵤₙᵢₜ for temperature control actions intended to lower the temperature of functional unit 105. In another example, vctrl1 may direct voltage control unit 215 to increase the voltage on voltage plane Vᵤₙᵢₜ for temperature control actions intended to allow for increased performance.

It should be noted that not all contemplated embodiments of the functional units as described herein include multiple temperature sensors 205 and a temperature sensor 210. In some embodiments, functional units may include only a single temperature sensor 205 and no temperature filter. Such an arrangement may be useful for functional units that have a small footprint on the IC die, or functional units wherein the thermal characteristics are such that the temperature is substantially consistent throughout.

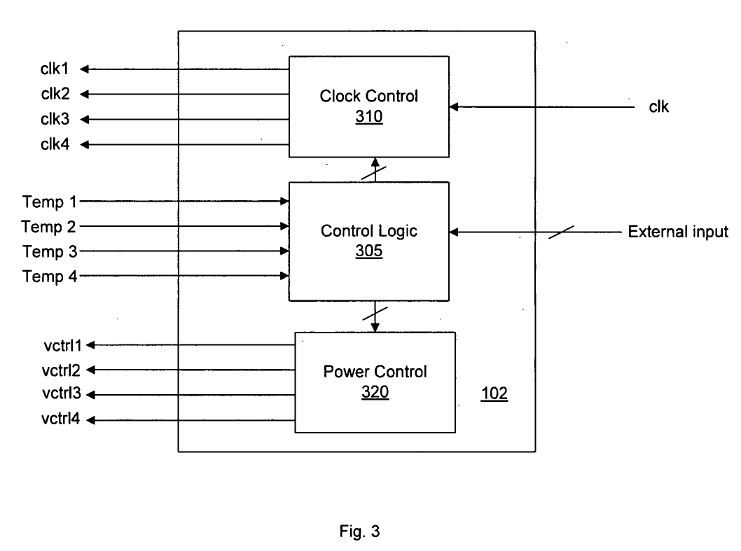

FIG. 3 is a block diagram of one embodiment of a temperature control unit. In the embodiment shown, temperature control unit 102 includes control logic 305, clock control logic 310, and power control unit 320. Control logic 305 in this particular example includes four temperature inputs, one each from four different functional units, and is also coupled to receive an external input. Temperature information is received through these inputs and provides a basis for control logic 305 to determine whether or not any temperature control actions are necessary. If it is determined that a temperature control action is necessary for one or more of the functional units, control logic 305 is configured to initiate such an action through control of one or both of clock control logic 310 and power control unit 310. Control logic 305 may also be configured to determine global extreme temperatures within the IC (e.g., a global high and a global low), and take actions based on these global temperatures and corresponding global thresholds (e.g., complete shutdown of the IC if a global maximum temperature threshold is exceeded.

The external input may provide a means for a user or an external device to program control logic 305 as to the desired or required response to various events. For example, control logic 305 may be programmed to first attempt to reduce the temperature by reducing the frequency of a clock signal (and possibly the voltage as well) to a particular functional unit, followed by a subsequent attempt to reduce temperature by reducing the clock frequency again. Furthermore, the external input may allow a path to input control signals for purposes other than temperature control (e.g., for placing the corresponding IC into a partial or full sleep mode). The external input may also be used to set temperature thresholds for which temperature control actions are to be taken. Setting the temperature thresholds may include setting temperature thresholds for the functional units individually, or setting temperature thresholds that apply to each of the functional units. A global temperature threshold may also be set, indicating a temperature at which, if exceeded, control logic 305 is programmed to shut down the IC in which it is implemented.

Control logic 305 may be further configured to store temperature history information and to calculate temperature gradient information based thereon. For example, control logic 305 may be configured to calculate the rise or fall of the temperature of a given functional unit over a certain time period. This temperature gradient information may also be used in determining whether a temperature control action is to be taken. For example, if control logic 305 determines that the temperature of a functional unit exceeds an intermediate threshold, and a calculated temperature gradient indicates that its temperature is rising rapidly, it may perform a temperature control action to reduce the frequency of the corresponding clock signal, even though the temperature has not yet exceeded a maximum threshold. Thus, the ability to determine temperature gradient information may further enhance the ability of TCU 102 to control the temperatures of the various functional units of the IC.

Clock control unit 310 is coupled to receive a system clock signal (clk) and to provide separate clock signals to each of the functional units (e.g., clk1 to a first functional unit, clk2 to a second functional unit, and so forth). In one embodiment, clock control unit 310 includes a plurality of independently controllable phase locked loops (PLLs), each coupled to receive the system clock signal and to provide a corresponding one of the clock signals to a functional unit. Alternatively, delay locked loops (DLLs) may be used in other embodiments. Clock control unit 310 is configured to adjust the frequency of each of clock signals clk1-clk4, independently of one another, based on signals received from control logic 305.

Changing the frequency of individual clock signals may be performed for temperature control purposes. For example, if a given functional unit is reporting a temperature over a predetermined threshold, control logic 305 may direct clock control unit 310 to reduce the frequency of its corresponding clock signal. Clock control unit 310 may also be capable of completely shutting down a given clock signal, which can occur for temperature control reasons or for power consumption reasons (i.e. for entering a sleep mode, as noted above). Since the clock signals are independently controllable, the other clock signals need not be affected by a frequency change of a particular one of the clock signals.

Power control unit 320 is configured to provide a corresponding voltage control signal to each of the functional units. In the embodiment shown, each of voltage control signals vctrl1-vctrl4 corresponds to a unique one of the functional units. Accordingly, power control unit 320 may control the power consumption of each of the functional units independently of one another, by controlling a power plane voltage for that particular unit. Each of the voltage control signals may be applied to a voltage control unit of a corresponding functional unit, such as voltage control unit 215 shown in FIG. 2. A voltage control signal generated by power control unit 320 may cause the voltage on the voltage plane of the corresponding functional unit to be increased, reduced, or shut down. These actions may be taken for the purposes of increasing performance (raising the voltage), reducing the temperature (reducing the voltage), or for conservation of power in times of low activity (reducing the voltage to zero).

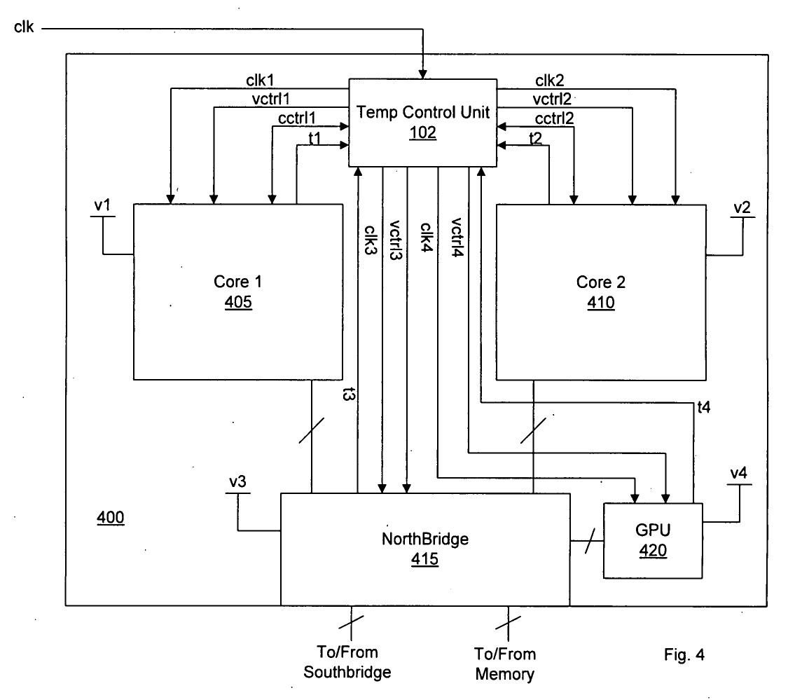

FIG. 4 is a block diagram of one embodiment of a multi-core processor configured for functional block level thermal control. In the embodiment shown, processor 400 includes four primary functional units—two processor cores 405 and 410, a memory controller hub (North Bridge 415), and a graphics processing unit (GPU) 420. A TCU 102 is coupled to each of these functional units and configured to perform temperature control actions on each, independently of any temperature control actions performed on other ones of the functional units. Processor 400 may also include additional functional units that are not explicitly shown here, as well as various types of logic for coupling the functional units together.

TCU 102 is coupled to receive temperature signals t1-t4, one each from each of the functional units as shown in the drawing. The temperature signals carry information regarding sensed temperatures in their respective functional units, and include at least a maximum temperature sensed. TCU 102 is configured to perform temperature control actions based on the temperature information provided via these temperature control signals.

Each of the functional units shown is coupled to receive corresponding clock signals from TCU 102, and is further coupled to receive corresponding voltage control signals. Each of the functional units shown in the embodiment of FIG. 4 is coupled to receive a clock signal that can be changed in frequency without affecting the other clock signals. Similarly, each of the functional units shown in the embodiment of FIG. 4 is coupled to receive a voltage control signal that can change the voltage on a corresponding voltage plane without affecting the voltages on the voltage planes of any of the other ones of the functional units. As discussed in the various embodiments above, TCU 102 may perform temperature control actions on each of the functional units. A temperature control action for a given functional unit may include adjusting the frequency of a clock signal received thereby, adjusting the voltage on a voltage plane of the functional unit, or a combination of both of these actions.

In embodiments such as the multi-core processor of FIG. 4, the temperature control requirements of the processor cores 405 and 410 may be different than those of other functional units. For example, the temperature thresholds for processor cores 405 and 410 may be different from the temperature thresholds for North Bridge 415 and GPU 420. Furthermore, processor cores 405 may have a greater number of thresholds than the other functional units, including a number of intermediate thresholds upon which temperature control actions may be taken.

In addition to the temperature signals, the clock signals, and the voltage control signals, processor cores 405 and 410 may also be coupled to TCU 102 by corresponding core control signals cctrl1 and ccrtl2, respectively. These control signals may be bi-directional and/or may be transmitted via multiple signal lines. Through the use of these signals, TCU 102 may monitor the processing load on each of processor cores 405 and 410, in addition to their temperatures. Therefore, in addition to controlling the clock frequency or the voltage of processor cores 405 and 410, TCU 102 may also perform temperature control actions that involve re-allocating the processing load between processor cores 405 and 410 in an effort to control their respective temperatures. For example, consider a situation where processor core 405 is under a heavy processing workload and reports a temperature that exceeds a predetermined threshold, while at the same time, processor core 410 is below the predetermined threshold and has significantly less processing workload. In such a situation, TCU 102 may attempt to reduce the temperature of processor core 405 by re-allocating a portion of its workload to processor core 410. Thus, TCU 102 may perform temperature control actions through workload allocation in addition to controlling clock frequency and temperature.

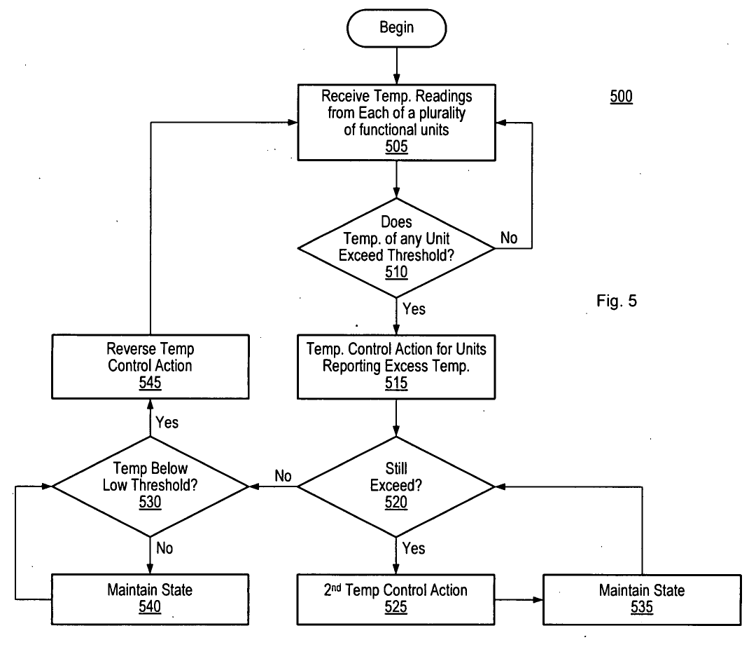

FIG. 5 is a flow diagram of one embodiment of a method for providing functional block level thermal control for an integrated circuit. Method 500 begins with the receiving of temperature readings from each of a plurality of functional units (505). It is then determined as to whether any of the received temperatures exceeds a temperature threshold (510). For each functional unit reporting a temperature that reports a temperature that exceeds a threshold (e.g., a maximum temperature threshold), a temperature control action is taken (515). The temperature control action may include any of the various temperature control actions discussed above, including changing a voltage, changing a frequency, or reallocating workload.

If, subsequent to a temperature control action, it is determined that a reported temperature from a functional unit continues to exceed a predetermined threshold value (520, yes), a second temperature control action can be taken (525). For example, if the first temperature control action was to reduce the clock frequency (and possibly the supply voltage) for the reporting functional unit, a second temperature control action may comprise a subsequent reduction of the clock frequency, as well as a reduction of the supply voltage for the reporting functional unit. A second temperature control action may also include a complete shutdown of the functional unit, if necessary to prevent damage thereto. In some embodiments, the decision to perform a temperature control action such as the second one discussed here may be based in full or in part on a calculated temperature gradient. For example, if a first temperature control action has been performed for a temperature that exceeded a threshold value, a decision to perform a second temperature control action may be based in full or in part on the amount the temperature has fallen in the time elapsed since the first temperature control action. Thus, in such embodiments, a second temperature control action may be performed even if the reported temperature has fallen below the threshold which was the basis for the first temperature control action.

In the embodiment shown, after the second temperature control action has been taken, the state of the functional unit may be maintained (535) until it is determined that the temperature threshold is no longer exceeded by the reported temperature (520, no). If a subsequently reported temperature from the functional unit no longer exceeds the threshold, a determination can then be made as to whether the subsequently reported temperature is below a low temperature threshold. If the temperature is not below the low threshold (530, no), the state of the functional unit is maintained (540). If the temperature is below the low threshold (530, yes), another temperature control action may be performed (545). This temperature control action may essentially be a reversal of the previous temperature control action (e.g., if clock frequency to a functional unit was reduced, the clock frequency in this action may be increased back to its previous value).

Many variations are possible and contemplated to the method described above. For example, a method based on multiple temperature thresholds with one or more intermediate thresholds is possible and contemplated. Thus, temperature control actions may be performed for a given functional unit each time its reported temperature crosses a predetermined temperature threshold. For example, an embodiment is contemplated wherein for each of a plurality of temperature ranges, the frequency of a clock signal for a functional unit is set to a predetermined value. In such an embodiment, each time the temperature reported by the functional unit exceeds one of the threshold values, its frequency is reduced to a value commensurate with a given temperature range. Similarly, each time the temperature falls below one of the threshold values, the frequency of the clock signal is increased.

As also noted above, temperature control actions may be performed on the basis of temperature, but also on the basis of calculated temperature gradients (i.e. the change of temperature over time), as well as on workload of certain functional units (e.g., comparative workload between multiple cores in a processor). Thus, the system and method for functional block level thermal control as described herein may provide a great deal of flexibility. The ability to independently control the frequencies of clock signals and supply voltages to the functional units may enable the temperature control functions to be integrated with other functions, such as power conservation functions. Furthermore, the ability to re-allocate processor core workloads in some embodiments may optimize both performance as well as thermal control.

While the present invention has been described with reference to particular embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. An integrated circuit comprising:
a plurality of functional units, wherein each of the plurality of functional units is implemented on a die of the integrated circuit, and wherein each of the functional units includes one or more temperature sensors; and
a temperature control unit coupled to each of the functional units, wherein the temperature control unit is configured to monitor a temperature of each of the plurality of functional units based on temperature information provided from the temperature sensors;
wherein, if the temperature exceeds a first threshold value for a particular one of the plurality of functional units, the temperature control unit is configured to perform a first temperature control action on the particular one of the plurality of functional units independently of other ones of the plurality of functional units.

2. The integrated circuit as recited in claim 1, wherein each of the plurality of functional units is configured to receive a corresponding one of a plurality of clock signals, and wherein the first temperature control action comprises reducing a frequency of the clock signal corresponding to the particular one of the plurality of functional units.

3. The integrated circuit as recited in claim 1, wherein each of the plurality of functional units is coupled to a corresponding one of a plurality of voltage planes, and wherein the first temperature control action comprises reducing a voltage present on the voltage plane corresponding to the particular one of the plurality of functional units.

4. The integrated circuit as recited in claim 3, wherein the first temperature control action comprises removing power from the particular one of the plurality of functional units.

5. The integrated circuit as recited in claim 1, wherein the integrated circuit is a processor, and wherein the plurality of functional units includes one or more of the following: one or more processor cores, a memory controller hub, a graphics processor.

6. The integrated circuit as recited in claim 5, wherein the temperatures control action comprises re-allocating a portion of a processing task from a first one of the processor cores to a second one of the processor cores.

7. The integrated circuit as recited in claim 1, wherein one or more of the functional units includes a plurality of temperature sensors coupled to a filter, wherein the filter is configured to provide a maximum temperature to the temperature control unit from among the plurality of temperature sensors of the functional unit.

8. The integrated circuit as recited in claim 1, wherein the temperature control unit is configured to perform a second temperature control action if the temperature of the particular one of the plurality of functional units continues to exceed the first threshold value for a predetermined time after the first temperature control action.

9. The integrated circuit as recited in claim 1, wherein the temperature control unit is configured to perform a second temperature control action if the temperature of the particular one of the plurality of functional units falls below a second threshold value.

10. The integrated circuit as recited in claim 9, wherein the temperature control unit is configured to perform a third temperature control action whenever the temperature of the particular one of the plurality of functional units crosses a third threshold value, wherein the third threshold value is between the first threshold value and the second threshold value.

11. A method comprising:
receiving temperature readings from each of a plurality of functional units implemented on an integrated circuit die;
determining if a temperature reading from any of the plurality of functional units exceeds a first threshold value; and
if the temperature exceeds the first threshold value for a particular one of the plurality of functional units, performing a first temperature control action on the particular one of the plurality of functional units independently of other ones of the plurality of functional units.

12. The method as recited in claim 11, wherein the first temperature control action comprises reducing a frequency of a clock signal provided to the particular one of the plurality of functional units independently of a frequency of corresponding clock signals provided to other ones of the plurality of functional units.

13. The method as recited in claim 11, wherein the first temperature control action comprises reducing a voltage on a voltage plane coupled to the particular one of the plurality of functional units independent of a voltage of voltage planes coupled to other ones of the plurality of functional units.

14. The method as recited in claim 13, wherein the first temperature control action comprises removing power from the particular one of the plurality of functional units.

15. The method as recited in claim 11, wherein the integrated circuit is a processor having at least a first processor core and a second processor core, and wherein the first temperature control action comprises re-allocating a portion of a processing task from the first processor core to the second processor core.

16. The method as recited in claim 11, further comprising:
performing a second temperature control action if the temperature of the particular one of the plurality of functional units continues to exceed the first threshold value for a predetermined time after the first temperature control action;
performing a third temperature control action if the temperature of the particular one of the plurality of functional units falls below a second threshold value; and
performing a fourth temperature control action whenever the temperature of the particular one of the plurality of functional units crosses a third threshold value, wherein the third threshold value is between the first threshold value and the second threshold value.

17. A processor comprising:
a plurality of functional units, the plurality of functional units including a first processor core, a second processor core, and a northbridge unit; and
a temperature control unit, wherein the temperature control unit is coupled to receive readings indicative of a temperature of each of the plurality of functional units; and
wherein, if the temperature exceeds a first threshold value for a particular one of the plurality of functional units, the temperature control unit is configured to perform a first temperature control action on the particular one of the plurality of functional units independently of other ones of the plurality of functional units.

18. The processor as recited in claim 17, wherein the first temperature control action comprises reducing a frequency of a clock signal provided to the particular one of the plurality of functional units independently of a frequency of corresponding clock signals provided to other ones of the plurality of functional units.

19. The processor as recited in claim 17, wherein the first temperature control action comprises reducing a voltage on a voltage plane coupled to the particular one of the plurality of functional units independent of a voltage of voltage planes coupled to other ones of the plurality of functional units.

20. The processor as recited in claim 17, wherein the first temperature control action comprises re-allocating a portion of a processing task from the first processor core to the second processor core.
